(19) United States
(12) Patent Application Publication
(10) Pub. No.: US 2006/0228895 A1
(43) Pub. Date: Oct. 12, 2006

(54) Method of forming fine pitch photoresist patterns using double patterning technique

(76) Inventors: Yun-sook Chae, Suwon-si (KR); Gyung-jin Min, Seoul (KR); Chul-ho Shin, Yongin-si (KR); Sang-wook Kim, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/357,131

(22) Filed: Feb. 21, 2006

(30) Foreign Application Priority Data
Apr. 6, 2005 (KR) 10-2005-0028533

(51) Int. Cl. H01L 21/302; H01L 21/461

(52) U.S. Cl. 438/725; 438/745

(57) ABSTRACT

A method of forming a photoresist pattern comprises providing a semiconductor substrate on which a layer to be etched is formed. The method further comprises forming a first photoresist pattern on the layer to be etched, processing the first photoresist pattern with hydrogen bromide (HBr) plasma, and forming a second photoresist pattern on the semiconductor substrate between the first photoresist patterns

### BACKGROUND OF THE INVENTION

1. Field of the Invention

Embodiments of the present invention relate generally to methods of forming photoresist patterns. More particularly, embodiments of the invention relate to methods of forming fine pitch photoresist patterns using a double patterning technique.

A claim of priority is made to Korean Patent Application No. 10-2005-0028533, filed on Apr. 6, 2005, the disclosure of which is hereby incorporated by reference in its entirety.

2. Description of Related Art

Researchers are continually searching for new ways to increase the performance of semiconductor devices such as computer memories and microprocessors. One of the main focuses of their research is developing techniques for fitting more electronic features such as transistors onto a small area of a wafer or substrate. In other words, the researchers seek to increase the performance of the semiconductor devices by increasing their integration density.

As the integration density of semiconductor devices increases, the line width and spacing of circuit elements in the semiconductor devices must decrease accordingly. For example, a dynamic random access memory (DRAM) device having a memory capacity of 1 gigabyte (GB) requires circuit elements to have a line width of less than 0.1 μm.

In general, the electronic features of a semiconductor device are formed using patterns created by a photolithography process or processes. Patterns used to form circuit elements with spacing and/or line widths less than a predetermined minimum amount are referred to in this written description as “fine pitch” patterns. One of the main factors that determines the minimum pitch of patterns that can be formed by a photolithography process is the type light source used in the photolithography process. For example, conventional photolithography processes commonly use light sources such as krypton fluoride (KrF) or argon fluoride (ArF) lasers, which have respective wavelengths of 248 nm or 193 nm. Unfortunately, the resolution of these KrF or ArF lasers is not high enough to produce the fine pitch patterns required to form 1 GB DRAM devices.

Because of this problem, the formation of fine pitch photoresist patterns is currently the subject of much research. One proposed method for forming fine pitch patterns is a double patterning method, in which two photolithography processes are successively performed. A conventional double patterning method is described with reference to FIGS. 1A and 1B.

Referring to FIG. 1A, a first photoresist film (not shown) is coated on a layer 10. The first photoresist film is then patterned by a first photolithography process to form a first photoresist pattern 20 having the minimum achievable feature spacing of the first photolithography process.

Referring to FIG. 1B, a second photoresist film (not shown) is coated on layer 10 over first photoresist pattern 20. The second photoresist film is then patterned by a second photolithography process to form a second photoresist pattern 30 between portions of first photoresist pattern 20. Second photoresist pattern 30 has the minimum achievable feature spacing of the second photolithography process. By forming first and second photoresist patterns 20 and 30 in successive steps, a resulting photoresist pattern including both of these photoresist patterns can have a pitch below the exposure limit of the first or second photolithography processes.

One shortcoming of the conventional double patterning method is known as an intermixing problem. In intermixing problem, first photoresist pattern 20 is deformed because it is formed before second photoresist pattern 30. In particular, in the process for forming second photoresist pattern 30, first photoresist pattern 20 is deformed since it is exposed together with second photoresist pattern 30.

FIG. 2 is a scanning electron micrograph (SEM) image showing a first photoresist pattern 20 and a second photoresist pattern 30 formed by a conventional double patterning method. Where first photoresist pattern 20 and second photoresist pattern 30 are designed to alternate, first photoresist pattern 20 is typically deformed to the shape of second photoresist pattern 30.

Where the intermixing problem results in deformed photoresist patterns, any circuit patterns formed by the photoresist patterns will tend to be deformed accordingly.

### SUMMARY OF THE INVENTION

Embodiments of the present invention provide methods of forming fine pitch photoresist patterns without the deformations that can result from the intermixing problem.

According to one embodiment of the invention, a method of forming a photoresist pattern comprises forming a first photoresist pattern on a layer to be etched, forming an intermixing prevention film on an upper surface of the first photoresist pattern, and forming a second photoresist pattern on the intermixing prevention film.

According to another embodiment of the invention, method of forming a photoresist pattern comprises providing a semiconductor substrate on which a layer to be etched is formed, forming a first photoresist pattern on the layer to be etched, processing the first photoresist pattern with hydrogen bromide (HBr) plasma, and forming a second photoresist pattern on the semiconductor substrate, between the first photoresist patterns.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIGS. 1A and 1B are cross-sectional views illustrating a conventional method of forming a photoresist pattern;

FIG. 2 is a SEM image showing a photoresist pattern formed by a conventional double patterning method;

FIGS. 3A through 3C are cross-sectional views illustrating a method of forming fine pitch photoresist patterns using a double patterning method according to one embodiment of the present invention;

FIG. 4 is a cross-sectional view illustrating a plasma chamber for performing a hydrogen bromide (HBr) plasma process according to one embodiment of present invention;

FIG. 5 is a magnified cross-sectional view of a photoresist pattern formed according an embodiment of the present invention;

FIGS. 6 through 8 are cross-sectional views illustrating several variations of the method illustrated in FIG. 3; and,

FIGS. 9 through 11 are SEM images showing photoresist patterns after performing an HBr plasma process according to embodiments of the present invention.

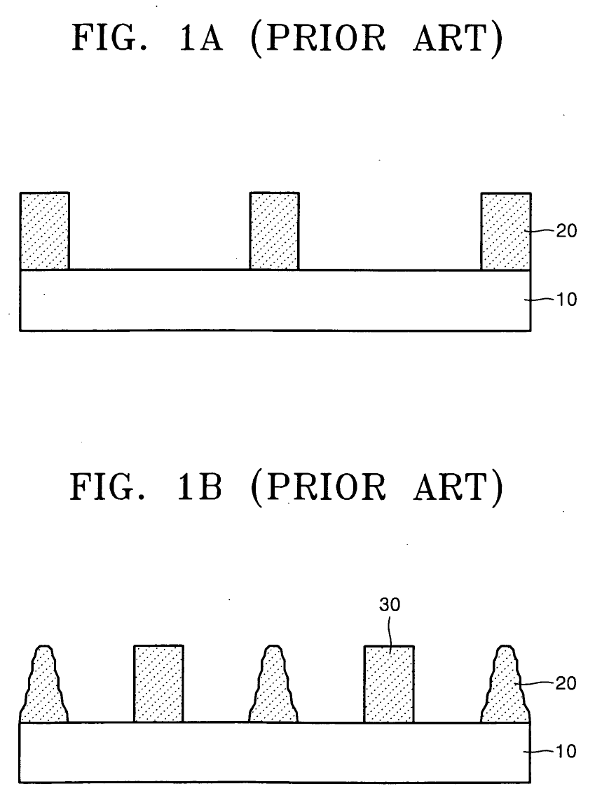

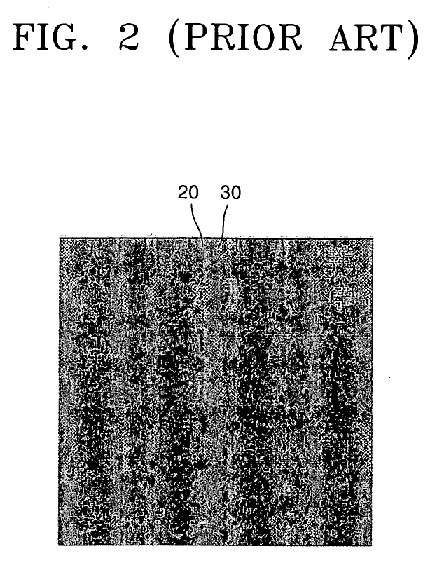

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

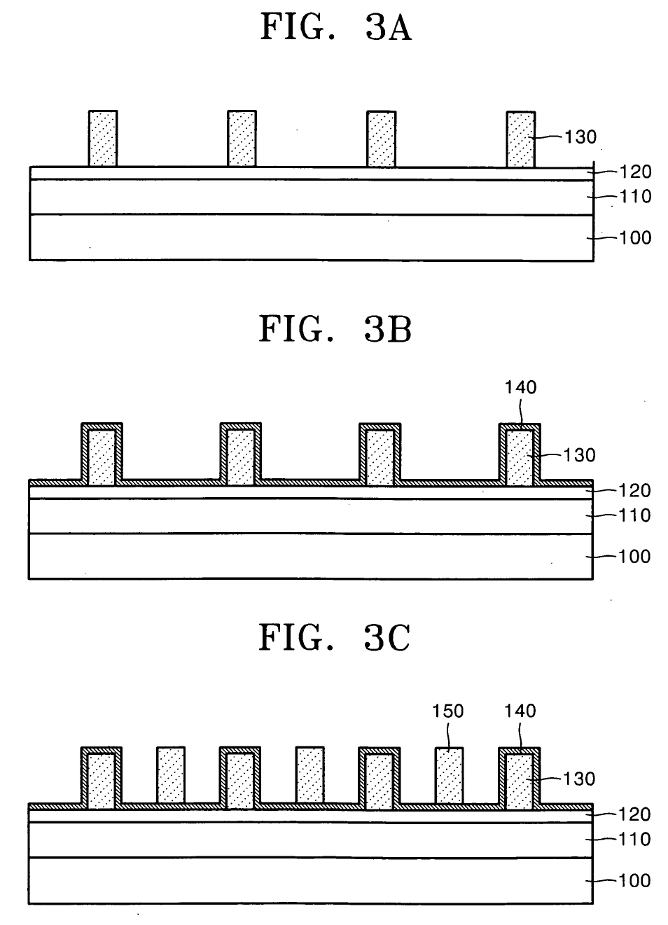

FIGS. 3A through 3C are cross-sectional views illustrating a method of forming fine pitch photoresist patterns using a double patterning method according to an embodiment of the present invention.

Referring to FIG. 3A, a layer 110 is formed on a semiconductor substrate 100. A bottom anti reflective coating (BARC) film 120 is then formed on layer 110. BARC film 120 comprises an organic material and is used to prevent diffused reflection in an exposure process used to form a first photoresist pattern 130. A first photoresist film (not shown) is formed on BARC film 120 and then first photoresist pattern 130 is formed by exposing and developing a portion of the first photoresist film. Preferably, first photoresist pattern 130 is formed to have the minimum feature size that can be attained by the exposing and developing processes.

Referring to FIG. 3B, a first intermixing prevention film 140 is formed on semiconductor substrate 100 over the surface of first photoresist pattern 130 and BARC film 120. First intermixing prevention film 140 is formed by processing exposed surfaces of first photoresist pattern 130 and BARC film 120 with HBr plasma.

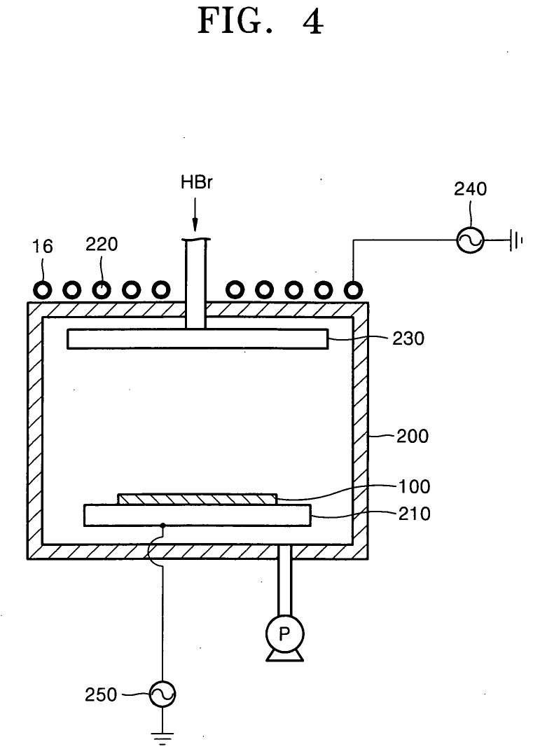

The HBr plasma processing can be performed using a plasma chamber 200 illustrated in FIG. 4. Plasma chamber 200 typically includes an electrostatic chuck 210 on which semiconductor substrate 100 is mounted, an upper electrode 220 formed on an upper outer or inner wall of plasma chamber 200, and a shower head 230 mounted at the top of plasma chamber 200 for supplying a process gas. Reference numeral “P” represents a pump for controlling pressure in plasma chamber 200.

The HBr plasma processing is typically performed by the following method. First, semiconductor substrate 100 on which first photoresist pattern 130 is formed is mounted on electrostatic chuck 210. Next, HBr gas is sprayed through shower head 230 into plasma chamber 200. Then, power is applied to upper electrode 220 and a bias power is applied to electrostatic chuck 210 to excite the HBr gas into a plasma state. The surface of semiconductor substrate 100 is then processed by the HBr plasma in plasma chamber 200.

Reference numeral 240 denotes a power source unit and reference numeral 250 denotes a bias power unit. Power source unit 240 generally provides a source power of about 10-2000 W to plasma chamber 200.

The HBr plasma processing in plasma chamber 200 can be performed by injecting only HBr gas. However, the HBr plasma processing can also use a mixture of hydrogen (H₂) gas, nitrogen (N₂) gas, or a hydrocarbon (CₓH_{y}) gas together with the HBr gas.

First intermixing prevention film 140, which results from the HBr plasma processing, typically comprises a polymer film and/or a portion of first photoresist pattern 130 that is hardened through cross-linking by the HBr plasma processing.

The thickness of first intermixing prevention film 140 generally varies according to the plasma processing time, which typically ranges from 10-300 seconds.

A standing wave 132 shown in FIG. 5 can occur on sidewalls of first photoresist pattern 130 when a line width of first photoresist pattern 130 is less than or equal to the wavelength of an exposure light source. However, first intermixing prevention film 140 tends to prevent the deformation of first photoresist pattern 130 due to standing wave 132.

The HBr plasma processing typically generates energy in the form of minute amounts of UV and heat, and various reactive species, such as ions and radicals. The energies and the reactive species can cause first photoresist pattern 130 to harden without changing its line width. Accordingly, the HBr plasma processing can improve an etching selectivity between first photoresist pattern 130 and layer 110.

Referring to FIG. 3C, a second photoresist film (not shown) is coated on semiconductor substrate 100 over first intermixing prevention film 140. The second photoresist film then patterned by exposure and development processes to form a second photoresist pattern 150 between features of first photoresist pattern 130. Because first photoresist pattern 130 is surrounded by first intermixing prevention film 140, it is not affected by light used to expose photoresist pattern 150. Accordingly, first intermixing prevention film 140 prevents first photoresist pattern 130 from being deformed.

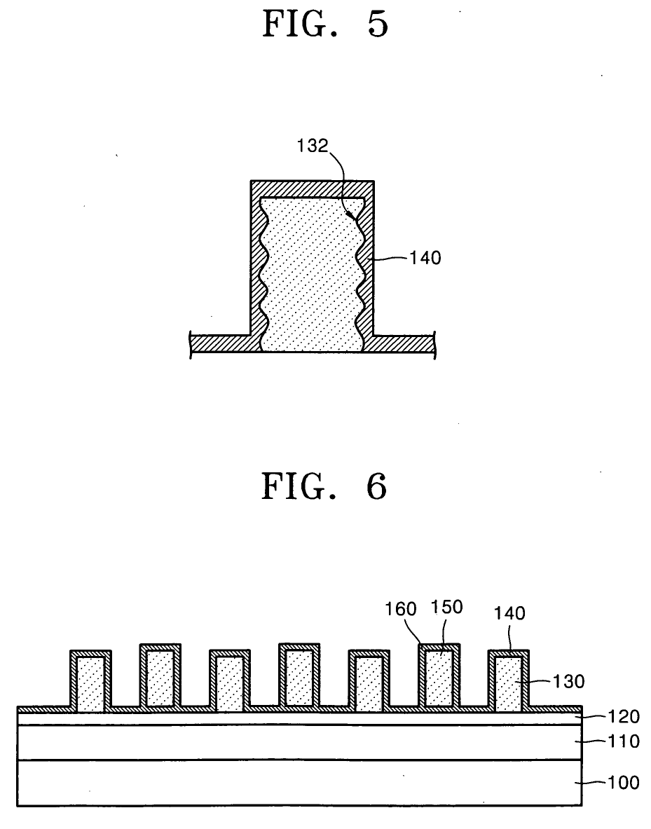

Referring to FIG. 6, a second intermixing prevention film 160 can be formed on the surface of second photoresist pattern 150 by performing another HBr plasma processing step after forming second photoresist pattern 150. The additional HBr plasma processing improves the etching selectivity between second photoresist pattern 150 and layer 110. In addition, second intermixing film 160 prevents deformation of second photoresist pattern 150 due to the formation of a standing wave on its sidewall.

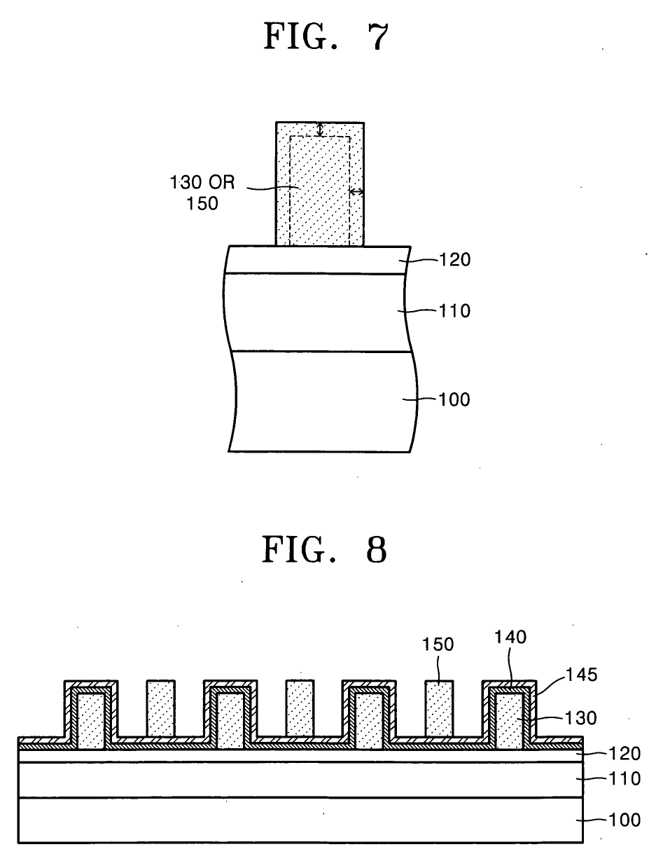

The HBr plasma processing may reduce or increase the line width of photoresist patterns 130 and 150. Accordingly, the critical dimension (CD) of a circuit pattern obtained by photoresist patterns 130 and 150 may vary. Such variation in the CD of the circuit patterns may be referred to as CD deformation. FIG. 7 illustrates a technique designed to address the problem of CD deformation. A shown in FIG. 7, the respective sizes of photoresist patterns 130 and 150 can be reduced by a predetermined amount in consideration an anticipated increase in size due to the HBr plasma processing. Such a reduction in the size of photoresist patterns 130 and 150 is known as a photoresist trimming process. The dotted line in the drawing denotes an ideal photoresist pattern 130 or 150, and the arrows indicate a portion of photoresist patterns 130 and 150 removed by the photoresist trimming process.

Referring to FIG. 8, a Hexamethyldisilazane (HMDS) film 145 can be formed on semiconductor substrate 100 over first intermixing film 140 before second photoresist pattern 150 is formed. HMDS film 145 improves adhesion between the second photoresist film and first intermixing prevention film 140, and is formed by spin coating. As a result, by forming HMDS film 145 before forming the second photoresist film, second photoresist pattern 150 will tend to adhere more firmly to intermixing prevention film 140.

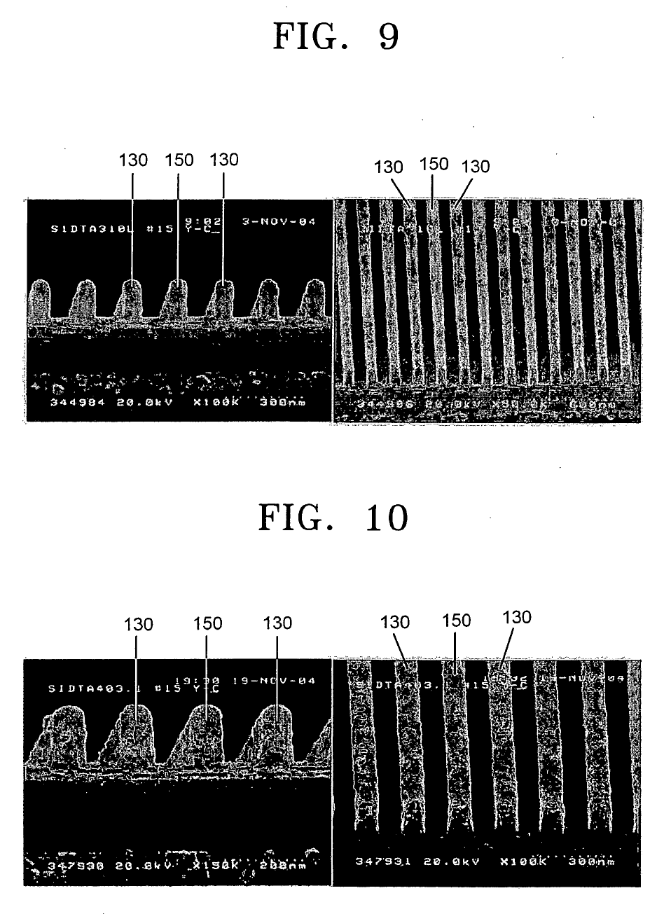

FIGS. 9 and 10 are SEM images showing photoresist patterns formed by methods including a HBr plasma processing step in accordance with selected embodiments of the present invention. In particular, the photoresist pattern shown in FIG. 9 was produced by performing the HBr plasma process for approximately 60 seconds, and the photoresist pattern shown in FIG. 10 was produced by performing the HBr plasma process for 180 seconds.

As seen in the SEM images of FIGS. 9 and 10, first photoresist pattern 130 maintains its shape after performing the HBr plasma process. In addition, as illustrated by a difference in the relative thicknesses of photoresist patterns 130 in FIGS. 9 and 10, the line widths of photoresist patterns 130 and 150 increase as the HBr plasma processing time increases. The increase in line width thickness is proportional to an increased thickness of intermixing prevention film 140 caused by the increased processing time of the HBr plasma processing.

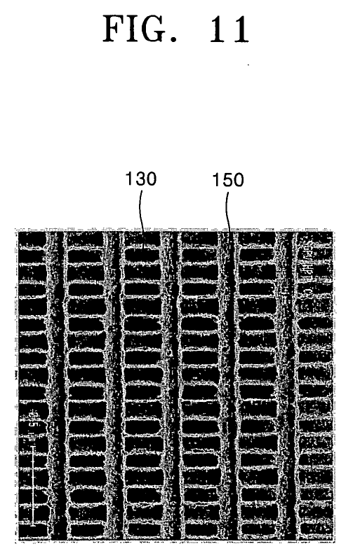

FIG. 11 is another SEM image showing a photoresist pattern after performing a HBr plasma processing step. In FIG. 11, first photoresist pattern 130 alternates with second photoresist pattern 150. As seen in FIG. 11, first photoresist pattern 130 is not damaged by the HBr plasma processing step.

As described above, embodiments of the present invention provide various methods of forming fine pitch photoresist patterns using a double patterning technique in which an exposure process is performed twice. These methods include a HBr plasma processing step, which is performed between forming a first photoresist pattern and a second photoresist pattern.

The HBr plasma processing step forms an intermixing prevention film on the surface of the first photoresist pattern. The intermixing prevention film prevents the shape of the first photoresist pattern from being deformed by a photolithography process used to form the second photoresist pattern.

The intermixing prevention film can also be used to maintain the uniformity of sidewalls in the first photoresist pattern. Furthermore, because reactive species generated during the HBr plasma processing step harden the first photoresist pattern, the HBr plasma processing step can also improve the etch selectivity between the first photoresist pattern and a layer to be etched using the first photoresist pattern.

The foregoing preferred embodiments are teaching examples. Those of ordinary skill in the art will understand that various changes in form and details may be made to the exemplary embodiments without departing from the scope of the present invention as defined by the following claims.

What is claimed is:

1. A method of forming a photoresist pattern, the method comprising:
forming a first photoresist pattern on a layer to be etched;
forming an intermixing prevention film on an upper surface of the first photoresist pattern; and,
forming a second photoresist pattern on the intermixing prevention film.

2. The method of claim 1, wherein forming the intermixing prevention film comprises processing the first photoresist pattern with hydrogen bromide (HBr) plasma.

3. The method of claim 2, wherein processing the first photoresist pattern with HBr plasma comprises:
loading a wafer on which the first photoresist pattern is formed on an electrostatic chuck of a plasma processing chamber;
injecting HBr gas into the plasma processing chamber; and,
applying power to an upper electrode and/or the electrostatic chuck of the plasma processing chamber.

4. The method of claim 3, wherein the power applied to the upper electrode and/or the electrostatic chuck has a level of 10-2000 watts.

5. The method of claim 3, further comprising:
injecting at least one of hydrogen gas (H₂), nitrogen gas (N₂), and a hydrocarbon gas (CₓH_{y}) into the plasma processing chamber.

6. The method of claim 1, wherein the second photoresist pattern is formed on the layer to be etched, between the first photoresist patterns.

7. The method of claim 1, further comprising:
processing the second photoresist pattern with HBr plasma.

8. The method of claim 1, wherein forming the first photoresist pattern includes trimming the first photoresist pattern.

9. The method of claim 1, further comprising:
coating a Hexamethyldisilazane (HMDS) film on the intermixing prevention film between forming the intermixing prevention film and forming the second photoresist pattern.

10. A method of forming a photoresist pattern, the method comprising:
providing a semiconductor substrate on which a layer to be etched is formed;
forming a first photoresist pattern on the layer to be etched;
processing the first photoresist pattern with hydrogen bromide (HBr) plasma; and,
forming a second photoresist pattern on the semiconductor substrate, between the first photoresist patterns.

11. The method of claim 10, wherein processing the first photoresist pattern with HBr plasma comprises:
loading the semiconductor substrate on an electrostatic chuck in a plasma processing chamber;
injecting HBr gas into the plasma processing chamber; and,
applying power to an upper electrode and/or the electrostatic chuck of the plasma processing chamber.

12. The method of claim 11, wherein the power applied to the upper electrode and/or the electrostatic chuck has a level of 10-2000 watts.

13. The method of claim 11, further comprising:
injecting at least one of hydrogen gas (H₂), nitrogen gas (N₂), and a hydrocarbon gas (CₓH_{y}) into the plasma processing chamber.

14. The method of claim 10 further comprising:
processing the second photoresist pattern with HBr plasma.

15. The method of claim 11, further comprising:
coating a Hexamethyldisilazane (HMDS) film on the intermixing prevention film between forming the intermixing prevention film and forming the second photoresist pattern.

16. The method of claim 10, wherein forming the first photoresist pattern includes trimming the first photoresist pattern.
